(19) United States
(12) Patent Application Publication
(10) Pub. No.: US 2024/0025385 A1
(43) Pub. Date: Jan. 25, 2024

(54) CONTROL UNIT FOR POWERING AN ELECTRICAL COMPONENT IN A VEHICLE AND A BRAKING SYSTEM

(71) Applicant: ZF Active Safety GmbH, Koblenz (DE)

(72) Inventor: Andreas Passmann, Hilgert (DE)

(21) Appl. No.: 18/354,904

(22) Filed: Jul. 19, 2023

(30) Foreign Application Priority Data
Jul. 19, 2022 (DE) 102022118073.5

(51) Int. Cl. B60T 8/88; H05K 7/02; B60R 16/03; B60T 13/68

(52) U.S. Cl. CPC B60T 8/885; H05K 7/02; B60R 16/0315; B60T 13/686; B60T 2270/402; B60T 2270/414; B60T 2240/00; B60T 2270/403

(57) ABSTRACT

A control unit in a vehicle for powering at least one electrical component in the vehicle has a first and a second electronic unit, each containing its own power supply, wherein the electrical component is arranged both in a circuit containing the power supply of the first electronic unit, and in a circuit containing the power supply of the second electronic unit and wherein both circuits contain an identical current path through the electrical component. The control unit may be part of a braking system of the vehicle, and the electrical components are, for example, coils of actuator valves of wheel brakes and/or current-carrying sensor components of wheel speed sensors.

### CROSS-REFERENCE TO RELATED APPLICATION

This application claims priority to German Priority Application No. 102022118073.5, filed Jul. 19, 2022, the disclosure of which is incorporated herein by reference in its entirety.

### TECHNICAL FIELD

The disclosure relates to a control unit in a vehicle for powering an electrical component and a braking system of a vehicle with such a control unit.

### BACKGROUND

For safety reasons, many components in the vehicle are designed redundantly. This also applies to the vehicle's braking system, which is designed to be as fail-safe as possible. However, the dual provision of components is both space-consuming and costly.

What is needed is to provide a safe power supply of components in a vehicle in which the number of redundant components can be reduced.

### SUMMARY

A control unit in a vehicle for the power supply of at least one electrical component in the vehicle, with a first and a second electronic unit, each containing its own power supply, wherein the electrical component is arranged both in a circuit containing the power supply of the first electronic unit, and in a circuit containing the power supply of the second electronic unit, wherein both circuits contain an identical current path through the electrical component.

The electrical component is connected in the control unit in such a way that both the power supply of the first electronic unit and the power supply of the second electronic unit can supply the power required for operation. Current flows through the electrical component identically in both circuits.

This arrangement makes it possible, despite the use of two independent current or voltage sources, to have certain current-carrying components, which are known to be very fail-safe, only once. This saves installation space and reduces costs.

In one exemplary arrangement, the two electronic units of the control unit are arranged completely independently of each other, so that in the event of failure of one of the electronic units, the other can take over the power supply of the electrical component alone. The power required for the power supply of the electrical component can therefore be provided entirely by each of the two control units alone.

In normal operation, the power supply for the respective electrical component is determined by a predetermined assignment. In normal operation, supply by both control units at the same time would also be conceivable.

The electrical component is basically a current-carrying component, which in turn is usually part of a larger modular unit, such as a coil of a solenoid valve or a Hall sensor.

In order to make the control unit as compact as possible, both electronic units are accommodated together in a housing of the control unit. The two electronic units can be arranged spatially close to each other. Where appropriate, their circuits may be placed on a common circuit board of the control unit.

In an exemplary arrangement, the control unit comprises at least one common area in which other electronic components are placed spatially adjacent to each other and which are electrically connected to at least one of the circuits, and wherein the electrical component is arranged in the common area or connected to it. In this way, for example, all circuit elements necessary for the operation of the component to which the electrical component belongs can be grouped into a single area of a circuit board.

At least one of these other electronic components may lie in the current path through the electrical component common to both circuits. These components also do not have to be kept redundant.

Physically, the common area is arranged in the middle between the circuits of the two electronic units. For example, several electrical components of the same type can be combined in a common area.

Where appropriate, several common areas may be provided for electrical components of different types.

For example, in the common area evaluation elements and/or filters are arranged, which are connected in particular to both electronic units. With the help of these elements, for example data evaluation and/or error control can be carried out.

In order to specify the current flow through the electrical component, in an exemplary variant the two power supplies are connected to the current path through the electrical component by diodes connected in opposite conducting directions in the two circuits. In this way, both power supplies can be permanently connected to the electrical component at the same time. This ensures that there is no current flow between the first and the second control units.

It is of course possible to arrange the circuits of the two electronic units in such a way that a current flow through the respective circuit can only take place after actuation of a suitable switch. For this purpose, for example, a transistor controllable by both electronic units may be arranged in the current path. This is also physically placed in the common area of the control unit.

The two electronic units are designed to communicate with each other. This can be done, for example, via an internal bus in the control unit. In this way, responsibilities of the individual electronic units can be defined in error situations, but also in normal operation.

It is advantageous if each of the electronic units has its own external electrical and/or electronic connections. A supply from an external voltage source can take place via these connections, for example. This may be formed, for example, by the vehicle's electrical system.

The connections can also be used to connect external components to the power supply of the respective electronic units. For example, any suitable sensors can be connected here.

These connections may also be used to communicate with other components and systems of the vehicle. For example, a connection to a general vehicle bus is conceivable.

In one exemplary arrangement, the connections are grouped together physically spatially adjacent to each other in a common terminal in each case.

In a possible exemplarily variant, the electrical component is formed by the windings of a coil of a solenoid valve. When actuated, the windings of the coil always carry current, which is supplied either by the power supply of the first electronic unit or that of the second electronic unit. In this way, a double coil winding, which has a winding permanently connected to the first electronic unit and a winding permanently connected to the second electronic unit, can be dispensed with.

In one exemplary arrangement, a measurement of the current coil current by both electronic units is possible. This can be achieved, for example, simply by a tapping via a resistor. These resistors can be arranged in the common area of the control unit.

The control unit may contain a hydraulic block. In this case, the fluid conducting components of the solenoid valve may be part of the hydraulic block.

In one exemplary arrangement, a plurality of valves, which belong, for example, to a braking system of the vehicle, can be arranged in close proximity to the common area of the control unit. The mechanical and fluid conducting components of the valves are inserted into a carrier of the hydraulic block. The coils of the valves can be placed directly on a circuit board in the control unit. In this way, the electronic and hydraulic control of a system can be realized in a very compact form.

The hydraulic block is responsible for controlling hydraulic circuits which are switched by the solenoid valves. The current for switching the solenoid valves is supplied by the two electronic units.

In another possible variant, the electrical component is a sensor component. This can be, for example, the current-carrying part of a Hall sensor.

For example, the sensor component may be part of a wheel speed sensor. However, the use of components of other sensors is also possible.

In one exemplary arrangement, the control unit is designed so that electrical components of different types can be addressed by the two electronic units. In this way, functions can be combined compactly and installation space can be saved.

Since the sensors are often located elsewhere in the vehicle than the control unit, it is advantageous if the sensor component is connected to the control unit and the two electronic units via an external connection.

In a possible exemplary variant, the current path runs through the sensor component through a connection of the control unit which is separate from the two electronic units, and which is connected to the sensor component. This connection may be, for example, a separate connection from the connecting terminals of the two electronic units described above. This is placed in the common area of the control unit. This terminal is then used for the power supply of the sensor component and, if appropriate, to transmit sensor data to the control unit.

In order to achieve the highest possible reliability, all connected sensor components, for example all wheel speed sensors of the vehicle, can each be connected to a separate contact of the terminal with a separate plug.

In another exemplary variant, the sensor component is connected to each of the electronic units via an external electrical and/or electronic connection of the respective electronic unit. For this purpose, connections of the terminal described above can be used. This has the advantage that no additional terminal is needed. In one exemplary arrangement, these connections are connected to the common area of the control unit, so that the circuit for power supply and optionally for error handling and signal processing as described above can be realized in the common area. Only the physical connections of the conductors to the sensor components are made via the connections of the two electronic units.

In both exemplary variants, the sensor component is connected to the common area of the control unit, wherein the connection is made either via the separate connection or via the connections of the electronic units.

Data evaluation, error control and/or signal filtering are carried out by circuit components in the common area of the control unit. Therefore these functions do not have to be provided redundantly in the sensors themselves.

An exemplary use of the control unit described above is in a braking system of a vehicle. The electrical components are, for example, coils of valves, for example actuator valves of wheel brakes or other valves of the braking system, and/or current-carrying sensor components of wheel speed sensors.

### BRIEF DESCRIPTION OF DRAWINGS

The disclosure is described in more detail below by several exemplary arrangements with reference to the attached figures. In the figures:

FIG. 1 shows a schematic representation of a control unit according to the disclosure;

FIG. 2 shows a schematic representation of the interconnections of a control unit according to the disclosure according to a first exemplary arrangement;

FIG. 3 shows a schematic representation of the interconnections of a control unit according to the disclosure according to a second exemplary arrangement;

FIG. 4 shows a schematic representation of a first exemplary variant of a connection of sensor components in the control unit from FIG. 3; and

FIG. 5 shows a schematic representation of a second exemplary variant of a connection of sensor components in the control unit from FIG. 3.

For the sake of clarity, not all identical components are always provided with reference signs.

Identical reference signs designate identical or substantially identical or identically functioning components and units in different exemplary arrangements.

### DETAILED DESCRIPTION

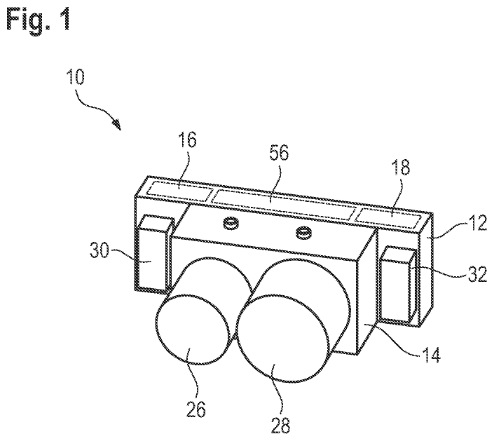

FIG. 1 shows a control unit 10 in a vehicle that is not shown in detail. Here the control unit 10 is part of a braking system that is also not shown of the vehicle and serves, for example, to actuate actuator valves of the wheel brakes and control valves of the brake circuits. In addition, the control unit 10 is connected here to sensors, for example wheel speed sensors, and collects and processes the data recorded by them.

In this example the control unit 10 contains an electronic block 12 and a hydraulic block 14, which are arranged in close proximity to each other and firmly connected to each other.

The hydraulic block 14 is used for the hydraulic control of all components of the control unit 10, which also have fluid conducting elements, such as all valves. The electrical and electronic elements of these components are controlled by the electronic block 12.

A first and a second electronic unit 16, 18 are formed in the electronic block 12 of the control unit 10.

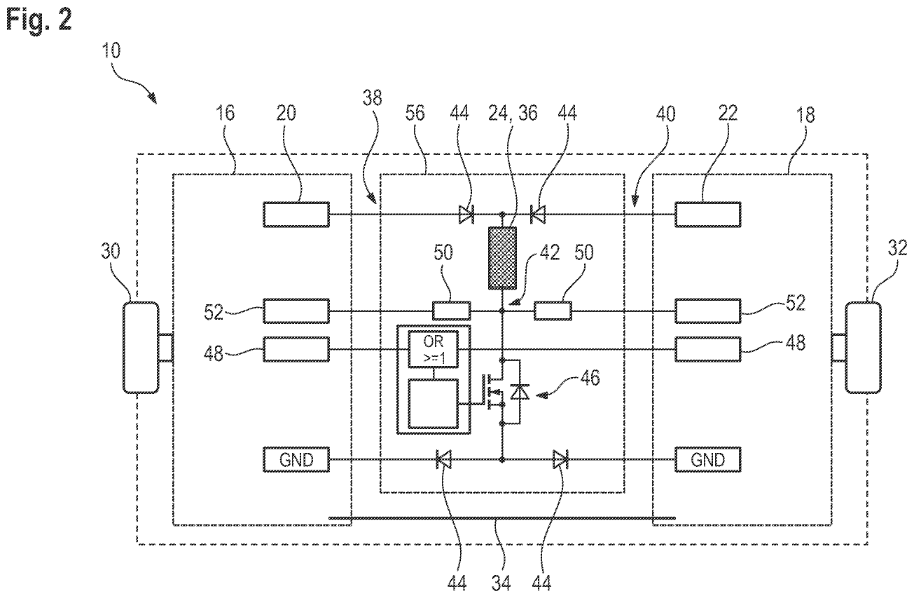

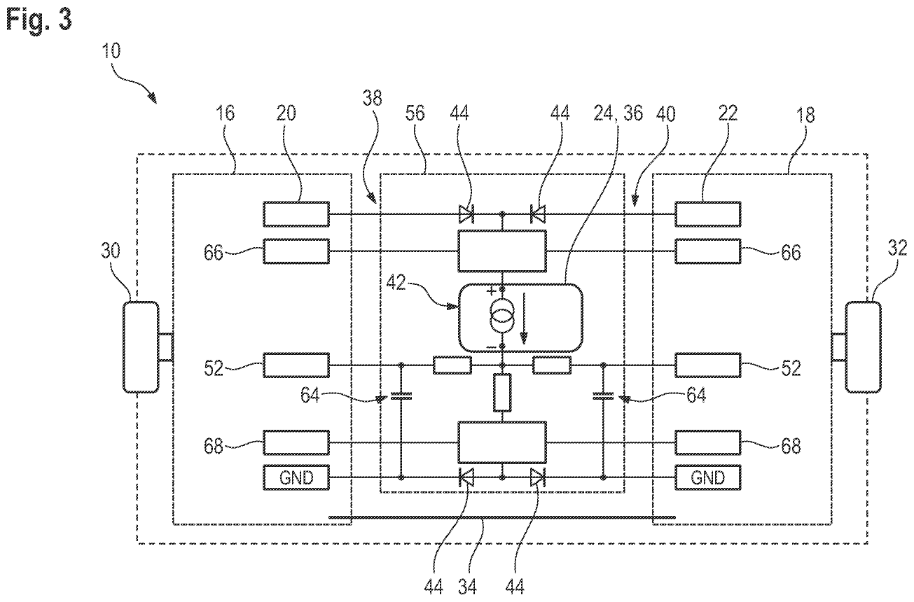

Each of the electronic units 16, 18 contains its own power supply 20, 22 (see FIGS. 2 and 3) for at least one electrical component 24 in the vehicle, here in the braking system of the vehicle.

In this example the power supply 20 is also connected to a first motor 26, while the power supply 22 is connected to a second motor 28 (see FIG. 1), wherein the motors 26, 28 generate fluid pressure in the hydraulic system.

Here each of the electronic units 16, 18 has an external electrical connection and/or electronic connections. In this example, these connections are each grouped in a terminal 30, 32. The terms “connections of the electronic units” and “terminals” are therefore used synonymously here.

The two electronic units 16, 18 are constructed independently of each other, so that each of them can continue to perform the tasks assigned to it in the event of failure of the other.

In addition, the two electronic units 16, 18 are designed for redundancy to such an extent that each of them can take over the power supply of the electrical component 24 completely even in the event of failure of the other electronic unit 18, 16.

The first electronic unit 16 can also supply the first motor 26 with power and has full access to the first terminal 30, even if the second electronic unit 18 should have completely failed. Conversely, even in the event of complete failure of the first electronic unit 16, the second electronic unit 18 can supply the second motor 28 with power and has access to the second terminal 32.

In this example, the two electronic units 16, 18 are connected to each other via an internal bus 34 of the control unit 10, so that they can communicate with each other in normal operation and optionally also in error conditions.

The electrical component 24, which is supplied with power from the control unit 10, is formed in a first exemplary variant shown in FIG. 2 by the windings 36 of a coil of a solenoid valve (not shown in detail). The solenoid valve here is one of the valves of the braking system but could also have another task.

The electrical component 24 is both part of a first circuit 38 and part of a second circuit 40, wherein the first circuit 38 contains the power supply 20 of the first electronic unit 16 in addition to the electrical component 24, and the second circuit 40 contains the power supply 22 of the second electronic unit 18 in addition to the electrical component 24.

A current path 42 through the electrical component 24, i.e. here through the windings 36 of the coil of the solenoid valve, is contained identically in both circuits 38, 40. The electrical component 24 is supplied in the same direction with the same polarity and with the same current flow both when energized by the power supply 20 and when energized by the power supply 22.

This is achieved by the use of a plurality of suitably connected diodes 44, each of which is connected in opposite directions such that the current supplied by the power supply 20 cannot flow to the power supply 22, and vice versa. The power supplies 20, 22 are permanently connected to the current path 42 via the diodes 44.

In this example, in addition to the electrical component 24, there is also a transistor 46 in the common current path 42 which can be addressed by both electronic units 16, 18. This can enable or prevent the current flow through the current path 42. The control of the transistor 46 is carried out here by control elements 48 in each of the electronic units 16, 18.

To determine the current coil current, each of the electronic units 16, 18 is connected to the current path 42 here via a suitable resistor 50. The voltage across the resistor 50 is a direct measure of the coil current. This signal is evaluated in suitable evaluation elements 52 in the respective electronic unit 16, 18 or transferred to a higher-level unit in the control unit 10. The measurement of the current through the current path 42 is thus possible redundantly in both electronic units 16, 18.

With regard to the coil current measurement and the control of the current flow through the windings 36 of the valve coil, the two electronic units 16, 18 are identically equipped here.

Physically, in this example, the first electronic unit 16 and the second electronic unit 18 are accommodated on circuit boards in the electronic block 12 of the control unit 10 (not shown). They can be arranged on a single circuit board.

The current path 42 containing the windings 36 of the coil of the solenoid valve, which forms the electrical component 24 here, as well as the transistor 46, the diodes 44 and the resistors 50, are physically arranged here in a section of a circuit board referred to as a common area 56. This common area 56 lies between the circuits of the first or second electronic unit 16, 18. The two electronic units 16, 18 are connected via suitable electrical conductors to the components in this common area 56 (see FIG. 2, for example).

In this example, a plurality of solenoids are arranged in close proximity to each other in one or more common areas 56 of the electronic block 12. They are placed directly on the circuit board of the common area 56, for example.

The respective hydraulic components of the associated solenoid valves are accommodated or formed in the hydraulic block 14. The solenoid valves are therefore part of both the electronic block 12 and the hydraulic block 14.

FIGS. 3 to 5 show another exemplary variant.

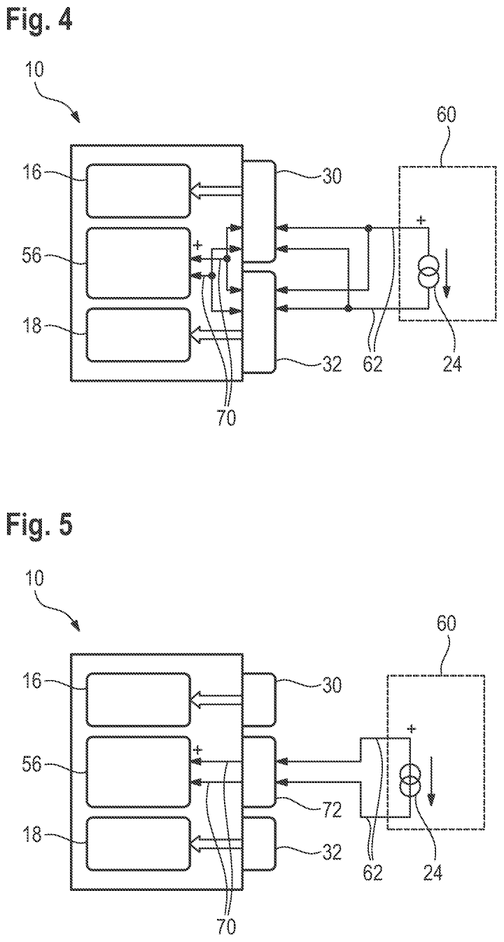

In this example, the electrical component 24 is a current-carrying sensor component, in this case a Hall sensor of a wheel speed sensor 60 (see also FIGS. 4 and 5).

As in the exemplary arrangement just described the electrical component 24 is part of a common current path 42, which belongs to both the first circuit 38 and the second circuit 40.

The basic structure of the two circuits 38, 40 does not differ from that described for the first exemplary arrangement.

The electronic components which serve to connect the two electronic units 16, 18 to the current path 42 or the power supply to the current path 42, are again arranged in a common area 56 of the electronic block 12 of the control unit 10 in this example.

If solenoid valves are also present, this may be the same area 56 as for the solenoid valves or a physically separated area.

Since the wheel speed sensors 60 are arranged on the individual wheels of the vehicle and thus generally away from the control unit 10, suitable electrical conductors 62 are provided between the control unit 10 and the respective wheel speed sensor 60 (see FIGS. 4 and 5). These conductors 62 all end in the common area 56 and are part of the current path 42. As a rule, a separate current path 42 is provided for each of the wheel speed sensors 60.

The circuit 38, 40 thus runs from the respective power supply 20, 22 into the common area 56, from there to the respective wheel speed sensor 60, back to the common area 56 and back to the respective power supply 20, 22.

As in the example of FIG. 2, the current flow into the circuits 38, 40 is directed by suitably switched diodes 44, which prevent a current flow between the power supplies 20, 22.

The evaluation elements 52 each contain here in each of the circuits 38, 40 a filter 64, here a low-pass, which filters out high-frequency interference from the signal to be evaluated.

Further evaluation elements 66, 68 are arranged in both circuits 38, 40 respectively between the electronic unit 16, 18 and the common current path 42 on both sides of the branch to the conductors 62 to the wheel speed sensor 60. These make it possible to check the contacting of the wheel speed sensor 60 on both sides of the sensor.

FIGS. 4 and 5 show two different variants for guiding the electrical conductors 62 from the wheel speed sensor 60 to the common area 56.

In the example of FIG. 4, each of the conductors 62 is branched in a y form, wherein one branch leads to the first terminal 30 and the second branch to the second terminal 32 of the first and the second electronic unit 16, 18. The branches can be placed in suitable positions at the discretion of the person skilled in the art.

Coming from terminals 30, 32, the branches of the individual wheel speed sensors 60 are combined again to conductors 70 that lead to the common area 56. The connection of the wheel speed sensors 60 to the terminals 30, 32 is thus designed redundantly in the current path 42 through the electrical component 24 as a single section.

In the example of FIG. 5, all conductors 62 lead to a connection that is separate from the terminals 30, 32, hereinafter referred to as the third terminal 72, which is arranged in the common area 56 or electrically connected to this via conductors 70. The third terminal 72 is electrically and physically separated from the two terminals 30, 32 of the first and second electronic units 16, 18.

For each of the wheel speed sensors 60, a separate conductor leads to the third terminal 72, which is optionally connected there to its own plug.

All features of the individual arrangements and variants can be freely exchanged or combined with each other at the discretion of the person skilled in the art. In particular, the control unit 10 may be designed for both valves and sensor components, which are arranged in different common areas of the control unit 10 as appropriate. In this case, all common areas are connected to both electronic units.

The control unit 10 could also be used in other areas of the vehicle for other tasks and with other electrical components. It is also conceivable to form the control unit 10 without a hydraulic block 14 and without the motors 26, 28.

1. A control unit in a vehicle for the power supply of at least one electrical component in the vehicle, comprising a first and a second electronic unit, each electronic unit containing its own power supply, wherein the electrical component is arranged both in a circuit that contains the power supply of the first electronic unit and in a circuit that contains the power supply of the second electrical unit wherein both circuits contain an identical current path through the electrical component.

2. The control unit according to claim 1, wherein both electronic units are accommodated together in a housing of the control unit.

3. The control unit according to claim 1, wherein the control unit comprises at least one common area in which other electronic components are spatially adjacent which are electrically connected to at least one of the circuits, and wherein the electrical component is arranged in the common area or is connected to it.

4. The control unit according to claim 3, wherein in the common area evaluation elements and/or filters are arranged, which are connected to both electronic units.

5. The control unit according to claim 1, wherein the two power supplies are connected to the current path through the electrical component by diodes connected in opposite directions in the two circuits.

6. The control unit according to claim 1, any one of the preceding claims, wherein the two electronic units are designed so that they communicate with each other.

7. The control unit according to claim 1, any one of the preceding claims, wherein each of the electronic units has its own external electrical and/or electronic connections.

8. The control unit according to claim 1, any one of the preceding claims, wherein the electrical component is formed by the windings of a coil of a solenoid valve.

9. The control unit according to claim 8, wherein a hydraulic block is included, and wherein the fluid conducting components of the solenoid valve are part of the hydraulic block.

10. The control unit according to claim 1, wherein the electrical component is a sensor component.

11. The control unit according to claim 10, wherein the sensor component is part of a wheel speed sensor.

12. The control unit according to any one of claim 10, wherein the current path through the sensor component runs through a connection of the control unit that is separate from the two electronic units and that is connected to the sensor component.

13. The control unit according to any one of claim 10, wherein the sensor component is connected to each of the electronic units via an external electrical and/or electronic connection of the respective electronic unit.

14. The control unit according to claim 12, wherein the sensor component is connected to the common area of the control unit via a separate connection or via connections of the electronic units.

15. A braking system of a vehicle having a control unit according to claim 1, wherein the electrical components are coils of actuator valves of wheel brakes, and/or current-carrying sensor components of wheel speed sensors.

16. The control unit according to claim 2, wherein the control unit comprises at least one common area in which other electronic components are spatially adjacent which are electrically connected to at least one of the circuits, and wherein the electrical component is arranged in the common area or is connected to it.

17. The control unit according to claim 16, wherein the two power supplies are connected to the current path through the electrical component by diodes connected in opposite directions in the two circuits.

18. The control unit according to claim 17, wherein the two electronic units are designed so that they communicate with each other.

19. The control unit according to claim 7, wherein the electrical component is a sensor component.

20. The control unit according to any one of claim 11, wherein the current path through the sensor component runs through a connection of the control unit that is separate from the two electronic units and that is connected to the sensor component.
